(19) United States
(12) Patent Application Publication
(10) Pub. No.: US 2007/0218571 A1
(43) Pub. Date: Sep. 20, 2007

(54) Disabling poorly testing RFID ICs

(75) Inventors: Anthony Stoughton, Seattle, WA (US); Ernest Allen, Seattle, WA (US)

Correspondence Address: SCHWEGMAN, LUNDBERG, WOESSNER & KLUTH/IMPINJ, PO BOX 2938, MINNEAPOLIS, MN, 55402, US

(73) Assignee: Impinj, Inc., Seattle, WA (US)

(21) Appl. No.: 11/519,507

(22) Filed: Sep. 11, 2006

Related U.S. Application Data
(63) Continuation-in-part of application No. 11/470,526, filed on Sep. 6, 2006.
(60) Provisional application No. 60/783,447, filed on Mar. 17, 2006.

(51) Int. Cl. G01R 31/26; H01L 21/66

(52) U.S. Cl. 438/14

(57) ABSTRACT

Manufacturing methods, testing, and RFID integrated circuit wafers that have been so prepared. A function of an integrated circuit can be tested. If the test fails, a control function of the tested circuit is disabled.

### CROSS-REFERENCE TO RELATED APPLICATIONS

This patent application is a continuation-in-part of co-pending U.S. patent application Ser. No. 11/470,526, Attorney Docket No: 2051.017US1, Client Matter No. IMPJ-0220, filed Sep. 6, 2006, entitled “Integrated Circuit Test Result Communication,” which claims the benefit of priority to U.S. Provisional Patent Application Ser. No. 60/783,447, filed Mar. 17, 2006, all of which are incorporated herein by reference and all commonly assigned herewith.

### TECHNICAL FIELD

The present description addresses the field of Radio Frequency IDentification (RFID) systems, and more specifically to methods of manufacturing and testing integrated circuits (ICs) for RFID tags.

### BACKGROUND INFORMATION

Radio frequency identification (RFID) systems may include RFID tags and RFID readers (the latter may also be known as RFID reader/writers or RFID interrogators). RFID systems can be used in many ways, including locating and identifying objects to which the tags are attached. RFID systems are particularly useful in product-related and service-related industries for tracking large numbers of objects being processed, inventoried, or handled. In such cases, an RFID tag is usually attached to an individual item, or to its package.

Radio Frequency IDentification (RFID) systems typically include RFID tags and RFID readers (the latter are also known as RFID reader/writers or RFID interrogators). RFID systems can be used in many ways for locating and identifying objects to which the tags are attached. RFID systems are particularly useful in product-related and service-related industries for tracking large numbers of objects being processed, inventoried, or handled. In such cases, an RFID tag is usually attached to an individual item, or to its package.

In principle, RFID techniques entail using an RFID reader to interrogate one or more RFID tags. The reader transmitting a Radio Frequency (RF) wave performs the interrogation. A tag that senses the interrogating RF wave responds by transmitting back another RF wave. The tag generates the transmitted back RF wave either originally, or by reflecting back a portion of the interrogating RF wave in a process known as backscatter. Backscatter may take place in a number of ways.

The reflected-back RF wave may further encode data stored internally in the tag, such as a number. The response is demodulated and decoded by the reader, which thereby identifies, counts, or otherwise interacts with the associated item. The decoded data can denote a serial number, a price, a date, a destination, other attribute(s), any combination of attributes, and so on.

An RFID tag typically includes an antenna system, a power management section, a radio section, and frequently a logical section, a memory, or both. In earlier RFID tags, the power management section included an energy storage device, such as a battery. RFID tags with an energy storage device are known as active tags. Advances in semiconductor technology have miniaturized the electronics so much that an RFID tag can be powered solely by the RF signal it receives. Such RFID tags do not include an energy storage device, and are called passive tags.

The electronic circuits of RFID tags are advantageously made from integrated circuit (IC) chips. When chips are manufactured, some are defective in a way that would result in poor performance, without actually failing. A problem is that such chips might still enter into the stream of commerce, against the wishes of their manufacturer.

### BRIEF SUMMARY

The present description gives instances of manufacturing methods, testing, and integrated circuit wafers that have been so prepared. In some embodiments, a function of an integrated circuit is tested. If the test fails, a control function of the tested circuit is disabled.

An advantage over the prior art is that a further sorting process can result in rejecting altogether an IC chip, which would otherwise perform poorly if assembled into a completed RFID tag. This will prevent the chip from entering the stream of commerce. This is especially useful where the further sorting process is performed by people and/or machines that are unable and/or unwilling to detect a poorly perform IC chip for rejecting it.

These and other features and advantages of this description will become more readily apparent from the following Detailed Description, which proceeds with reference to the drawings, in which:

### BRIEF DESCRIPTION OF THE DRAWINGS

FIG. 1 is a block diagram of components of an RFID system.

FIG. 2 is a diagram showing components of a passive RFID tag, such as a tag that can be used in the system of FIG. 1.

FIG. 3 is a conceptual diagram for explaining a half-duplex mode of communication between the components of the RFID system of FIG. 1.

FIG. 4 is a block diagram of an implementation of an electrical circuit formed in an IC of the tag of FIG. 2.

FIG. 5 is a flowchart illustrating a testing method according to embodiments.

FIG. 6A is a diagram of a wafer formed with RFID ICs according to a first operation of the flowchart of FIG. 5 according to embodiments.

FIG. 6B is a diagram for visualizing grades from a testing operation of the flowchart of FIG. 5 according to embodiments.

FIG. 6C is a diagram of the wafer of FIG. 6A after the testing operation of FIG. 6B, and where some of the RFID ICs are intact, while others, according to another operation of the flowchart of FIG. 5, have had one of their control functions disabled depending on the result of the testing operation of FIG. 6B.

FIG. 6D is a conceptual diagram illustrating separation of the wafer of FIG. 6C into multiple integrated circuit (IC) chips according to another operation of the flowchart of FIG. 5.

FIG. 7 is a block diagram of one of the chips of FIG. 6D, whose IC has not been disabled.

FIG. 8 is a block diagram of one of the chips of FIG. 6D, whose IC has had one of its control functions disabled.

FIG. 9 is the block diagram of FIG. 4, modified to further show that a modulator can be changed to disable the control function of the IC of FIG. 8.

FIG. 10 is the block diagram of FIG. 4, modified to further show that a demodulator can be changed to disable the control function of the IC of FIG. 8.

FIG. 11 is the block diagram of FIG. 4, modified to further show that the whole circuit can be disabled.

FIG. 12 is the block diagram of FIG. 4, modified to further show that a circuit can be logically killed to disable the control function of the IC of FIG. 8.

FIG. 13 is a diagram showing an arrangement for sorting the IC chips generated at FIG. 6D.

### DETAILED DESCRIPTION

As has been mentioned, the present description is about manufacturing methods, testing, and integrated circuit wafers that have been so prepared. The subject is now described in more detail.

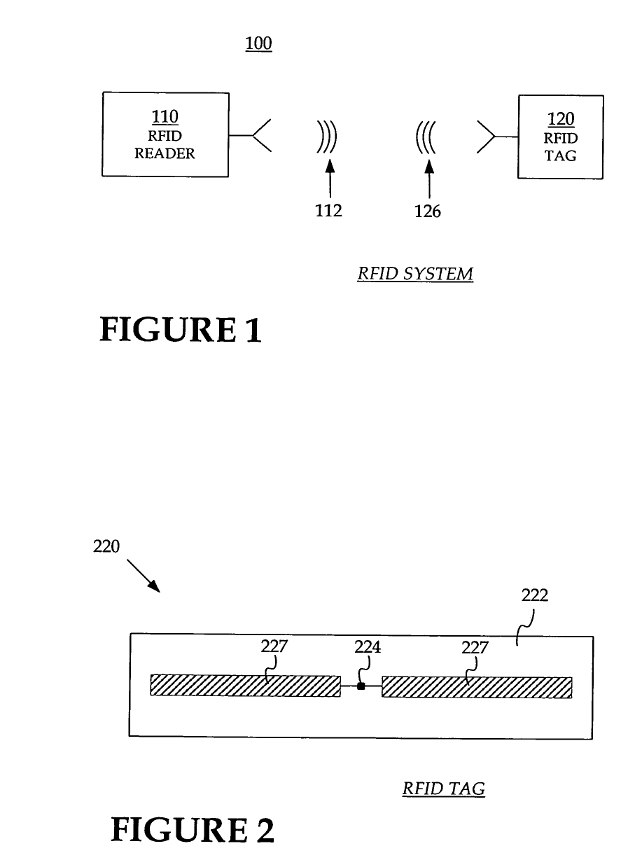

FIG. 1 is a diagram of components of a typical RFID system 100, incorporating aspects of the invention. An RFID reader 110 transmits an interrogating Radio Frequency (RF) wave 112. RFID tag 120 in the vicinity of RFID reader 110 may sense interrogating RF wave 112, and generate wave 126 in response. RFID reader 110 senses and interprets wave 126.

Reader 110 and tag 120 exchange data via wave 112 and wave 126. In a session of such an exchange, each encodes, modulates, and transmits data to the other, and each receives, demodulates, and decodes data from the other. The data is modulated onto, and decoded from, RF waveforms.

Encoding the data in waveforms can be performed in a number of different ways. For example, protocols are devised to communicate in terms of symbols, also called RFID symbols. A symbol for communicating can be a delimiter, a calibration symbol, and so on. Further symbols can be implemented for ultimately exchanging binary data, such as “0” and “1”, if that is desired. In turn, when the waveforms are processed internally by reader 110 and tag 120, they can be equivalently considered and treated as numbers having corresponding values, and so on.

Tag 120 can be a passive tag or an active tag, i.e. having its own power source. Where tag 120 is a passive tag, it is powered from wave 112.

FIG. 2 is a diagram of an RFID tag 220, which can be the same as tag 120 of FIG. 1. Tag 220 is implemented as a passive tag, meaning it does not have its own power source. Much of what is described in this document, however, applies also to active tags.

Tag 220 is formed on a substantially planar inlay 222, which can be made in many ways known in the art. Tag 220 includes an electrical circuit, which is preferably implemented in an integrated circuit (IC) 224. IC 224 is arranged on inlay 222.

IC 224 can be manufactured using IC manufacturing techniques that are known, once it is determined what circuit exactly they are supposed to implement. For the particular case of RFID ICs, once they are manufactured, they are also optionally tested. As explained later in this document, this description is related to such testing of RFID ICs and further treatment depending on the testing.

Still referring to FIG. 2, tag 220 also includes an antenna for exchanging wireless signals with its environment. The antenna is usually flat and attached to inlay 222. IC 224 is electrically coupled to the antenna via suitable antenna ports (not shown in this figure).

The antenna may be made in a number of ways, as is well known in the art. In the example of FIG. 2, the antenna is made from two distinct antenna segments 227, which are shown here forming a dipole. Many other embodiments are possible, using any number of antenna segments.

In some embodiments, an antenna can be made with even a single segment. Different places of the segment can be coupled to one or more of the antenna ports of IC 224. For example, the antenna can form a single loop, with its ends coupled to the ports. When the single segment has more complex shapes, it should be remembered that at, the frequencies of RFID wireless communication, even a single segment could behave like multiple segments.

In operation, a signal is received by the antenna, and communicated to IC 224. IC 224 both harvests power, and responds if appropriate, based on the incoming signal and its internal state. In order to respond by replying, IC 224 modulates the reflectance of the antenna, which generates the backscatter from a wave transmitted by the reader. Coupling together and uncoupling the antenna ports of IC 224 can modulate the reflectance, as can a variety of other means.

In the embodiment of FIG. 2, antenna segments 227 are separate from IC 224. In other embodiments, antenna segments may alternately be formed on IC 224, and so on.

The components of the RFID system of FIG. 1 may communicate with each other in any number of modes. One such mode is called full duplex. Another such mode is called half-duplex, and is described below.

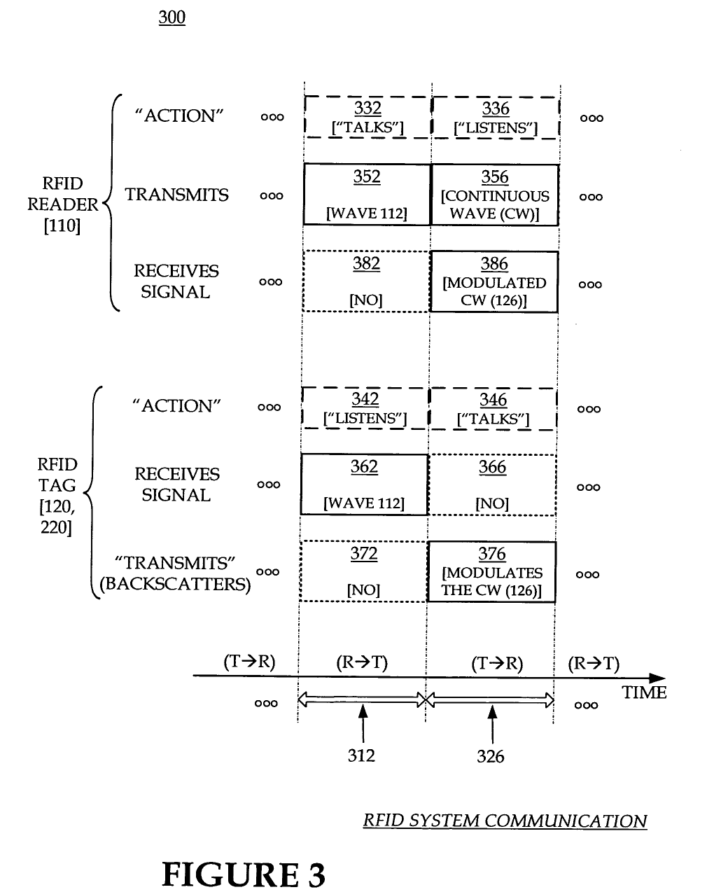

FIG. 3 is a conceptual diagram 300 for explaining the half-duplex mode of communication between the components of the RFID system of FIG. 1, especially when tag 120 is implemented as passive tag 220 of FIG. 2. The explanation is made with reference to a TIME axis, and also to a human metaphor of “talking” and “listening”. The actual technical implementations for “talking” and “listening” are now described.

RFID reader 110 and RFID tag 120 talk and listen to each other by taking turns. As seen on axis TIME, when reader 110 talks to tag 120 the communication session is designated as “R□T”, and when tag 120 talks to reader 110 the communication session is designated as “T□R”. Along the TIME axis, a sample R□T communication session occurs during a time interval 312, and a following sample T□R communication session occurs during a time interval 326. Of course interval 312 is typically of a different duration than interval 326—here the durations are shown approximately equal only for purposes of illustration.

According to blocks 332 and 336, RFID reader 110 talks during interval 312, and listens during interval 326. According to blocks 342 and 346, RFID tag 120 listens while reader 110 talks (during interval 312), and talks while reader 110 listens (during interval 326).

In terms of actual technical behavior, during interval 312, reader 110 talks to tag 120 as follows. According to block 352, reader 110 transmits wave 112, which was first described in FIG. 1. At the same time, according to block 362, tag 120 receives wave 112 and processes it, to extract data and so on. Meanwhile, according to block 372, tag 120 does not backscatter with its antenna, and according to block 382, reader 110 has no wave to receive from tag 120.

During interval 326, tag 120 talks to reader 110 as follows. According to block 356, reader 110 transmits a Continuous Wave (CW), which can be thought of as a carrier signal that ideally encodes no information. As discussed before, this carrier signal serves both to be harvested by tag 120 for its own internal power needs, and also as a wave that tag 120 can backscatter. Indeed, during interval 326, according to block 366, tag 120 does not receive a signal for processing. Instead, according to block 376, tag 120 modulates the CW emitted according to block 356, so as to generate backscatter wave 126. Concurrently, according to block 386, reader 110 receives backscatter wave 126 and processes it.

In the above, an RFID reader/interrogator may communicate with one or more RFID tags in any number of ways. Some such ways are called protocols. A protocol is a specification that calls for specific manners of signaling between the reader and the tags.

One such protocol is called the Specification for RFID Air Interface-EPC (TM) Radio-Frequency Identity Protocols Class-1 Generation-2 UHF RFID Protocol for Communications at 860 MHz-960 MHz, which is also colloquially known as “the Gen2 Spec”. The Gen2 Spec has been ratified by EPCglobal, which is an organization that maintains a website at: <http://www.epcglobalinc.org/> at the time this document is initially filed with the USPTO.

It was described above how reader 110 and tag 120 communicate in terms of time. In addition, communications between reader 110 and tag 120 may be restricted according to frequency. One such restriction is that the available frequency spectrum may be partitioned into divisions that are called channels. Different partitioning manners may be specified by different regulatory jurisdictions and authorities (e.g. FCC in North America, CEPT in Europe, etc.).

The reader 110 typically transmits with a transmission spectrum that lies within one channel. In some regulatory jurisdictions the authorities permit aggregating multiple channels into one or more larger channels, but for all practical purposes an aggregate channel can again be considered a single, albeit larger, individual channel.

Tag 120 can respond with a backscatter that is modulated directly onto the frequency of the reader's emitted CW, also called baseband backscatter. Alternatively, Tag 120 can respond with a backscatter that is modulated onto a frequency, developed by Tag 120, that is different from the reader's emitted CW, and this modulated tag frequency is then impressed upon the reader's emitted CW. This second type of backscatter is called subcarrier backscatter. The subcarrier frequency can be within the reader's channel, can straddle the boundaries with the adjacent channel, or can be wholly outside the reader's channel.

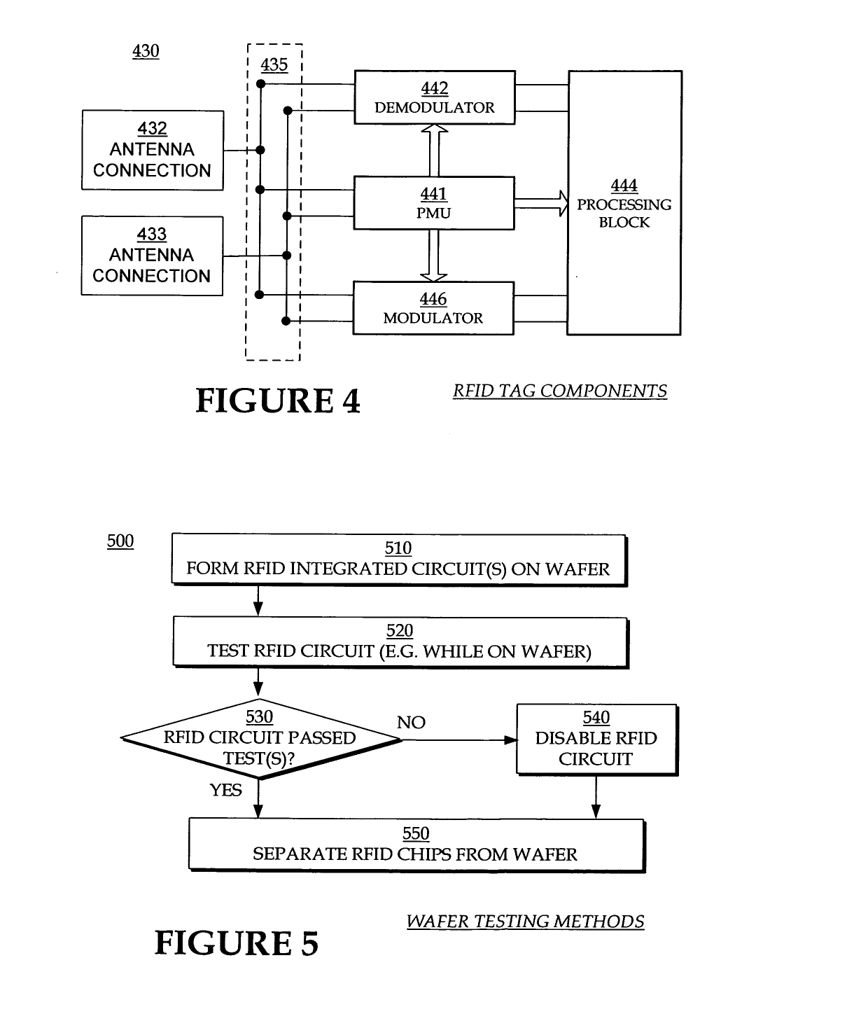

FIG. 4 is a block diagram of an electrical circuit 430. Circuit 430 may be formed in an IC of an RFID tag, such as IC 224 of FIG. 2. Circuit 430 has a number of main components that are described in this document. Circuit 430 may have a number of additional components from what is shown and described, or different components, depending on the exact implementation.

Circuit 430 includes at least two antenna connections 432, 433, which are suitable for coupling to one or more antenna segments (not shown in FIG. 4). Antenna connections 432, 433 may be made in any suitable way, such as pads and so on. In a number of embodiments more than two antenna connections are used, especially in embodiments where more antenna segments are used.

Circuit 430 includes a section 435. Section 435 may be implemented as shown, for example as a group of nodes for proper routing of signals. In some embodiments, section 435 may be implemented otherwise, for example to include a receive/transmit switch that can route a signal, and so on.

Circuit 430 also includes a Power Management Unit (PMU) 441. PMU 441 may be implemented in any way known in the art, for harvesting raw RF power received via antenna connections 432, 433. In some embodiments, PMU 441 includes at least one rectifier, and so on.

In operation, an RF wave received via antenna connections 432, 433 is received by PMU 441, which in turn generates power for components of circuit 430. This is true for either or both R□T and T□R sessions, whether or not the received RF wave is modulated.

Circuit 430 additionally includes a demodulator 442. Demodulator 442 demodulates an RF signal received via antenna connections 432, 433. Demodulator 442 may be implemented in any way known in the art, for example including an attenuator stage, amplifier stage, and so on.

Circuit 430 further includes a processing block 444. Processing block 444 receives the demodulated signal from demodulator 442, and may perform operations. In addition, it may generate an output signal for transmission.

Processing block 444 may be implemented in any way known in the art. For example, processing block 444 may include a number of components, such as a processor, a memory, a decoder, an encoder, and so on.

Circuit 430 additionally includes a modulator 446. Modulator 446 modulates an output signal generated by processing block 444. The modulated signal is transmitted by driving antenna connections 432, 433, and therefore driving the load presented by the coupled antenna segment or segments. Modulator 446 may be implemented in any way known in the art, for example including a driver stage, amplifier stage, and so on.

In one embodiment, demodulator 442 and modulator 446 may be combined in a single transceiver circuit. In another embodiment, modulator 446 may include a backscatter transmitter or an active transmitter. In yet other embodiments, demodulator 442 and modulator 446 are part of processing block 444.

It will be recognized at this juncture that circuit 430 can also be the circuit of an RFID reader according to the invention, without needing PMU 441. Indeed, an RFID reader can typically be powered differently, such as from a wall outlet, a battery, and so on. Additionally, when circuit 430 is configured as a reader, processing block 444 may have additional Inputs/Outputs (I/O) to a terminal, network, or other such devices or connections.

In terms of processing a signal, circuit 430 operates differently during a R□T session and a T□R session, in treating a signal. More particularly, during a R□T session demodulator 442 is used, while during a T□R session modulator 446 is used.

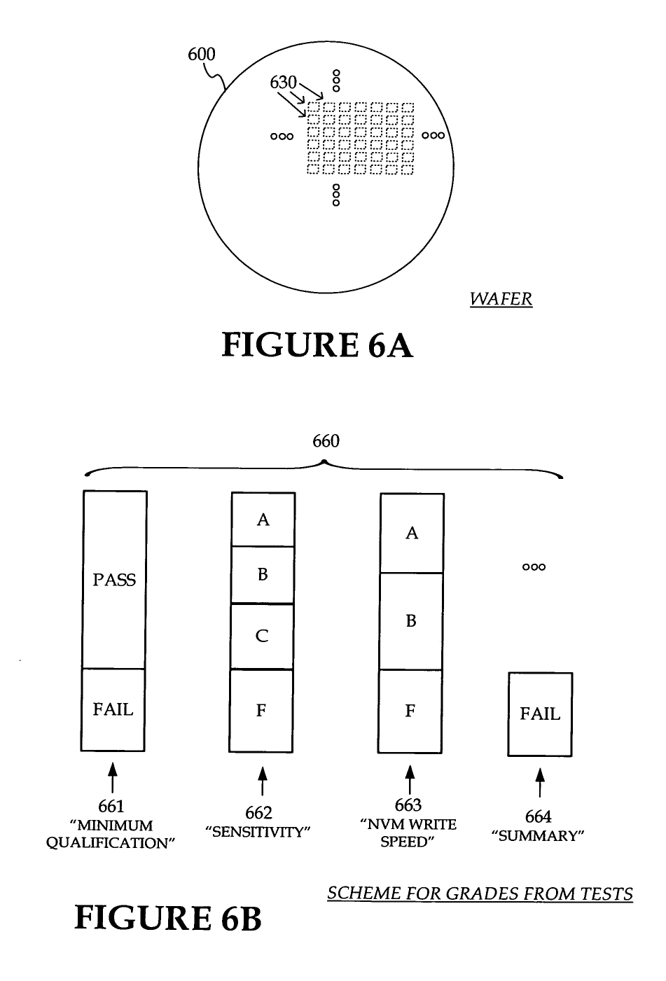

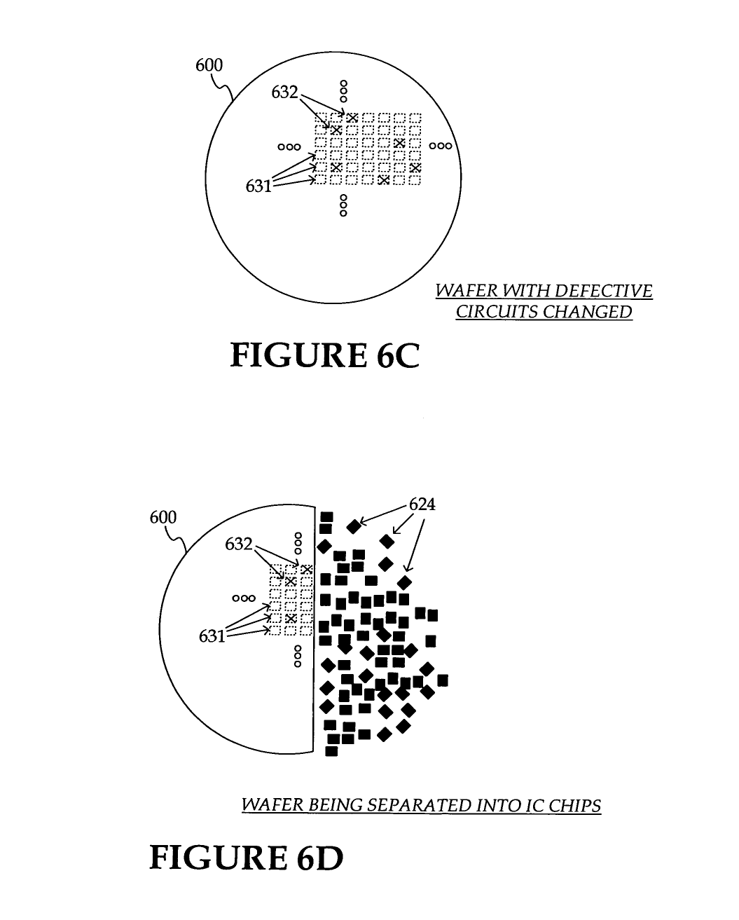

Methods according to the invention are now described with reference to FIG. 5, along with FIGS. 6, 7, 8, 9, 10, 11 and 12.

FIG. 5 shows a flowchart 500 for describing a method. According to an operation 510, RFID circuits are formed on a wafer. These are circuits that can be used ultimately for making integrated RFID circuit 224 of RFID tag 220 of FIG. 2. Forming may be performed in any number of ways. One such way is described below.

Referring now to FIG. 6A, a wafer 600 can be made out of silicon or other suitable material for forming an integrated circuit thereon. RFID integrated circuits 630 are formed on wafer 600, as is known in the art. In terms of components, circuits 630 can be as shown for circuit 430 in FIG. 4. Only some circuits 630 are shown on wafer 600, but it is usually more efficient to cover as much as possible of the area of wafer 600 with circuits 630.

As is well known, the manufacture of operation 510 can result in some of the circuits to be formed with defects, and which are thrown out. Good processes and planning keep the percentage of these defective RFID chips to a minimum.

Returning to FIG. 5, according to a next operation 520, the RFID circuits formed at operation 510 are tested.

Testing may be performed in any number of ways. In some embodiments, the wafer is physically probed to test the first operative function. In other embodiments, the formed RFID circuit that is being tested includes an on-chip antenna. RF energy is directed at that antenna, to test the first operative function. Ideally, such testing is automated.

Testing can be for one or more operative functions of one or more of the RFID circuits. These operative functions can be of the components of the circuit, some of which are shown in FIG. 4, or performance of the circuit, as is further detailed below. The operative functions can exhibit poor performance when their respective components have defects in the manufacture, as described above.

According to a next operation 530, it is determined whether a certain tested RFID circuit has passed the test of operation 520. For that, some definition is preferably used as to what constitutes passing, and what constitutes failing. For example, a test can result in a grade, and the determination can be made depending on whether the grade is higher or lower than a threshold, depending on the arrangement.

Grades can some times be expressed as scores, reflecting a degree of performance or capability. Such possible grades can be “A”, “B”, . . . , “F”; “10%”, . . . , “70%”, . . . , “100%”; “MINIMAL”, “AVERAGE”, “PREMIUM”, “PASS”, “FAIL”, etc.

Referring now to FIG. 6B, sample test results are shown along grading scales. Along a scale 662, results are shown for sensitivity. Along scale 663, results are shown for the write speed of a non volatile memory of circuit 430 (not shown in circuit 430). In these scales, “F” can stand for fail, while all other higher grades can amount to passing.

In some instances, for example, a tested circuit may be deemed to pass one test, but fail another. For this kind of reason, composite grading may be used advantageously. For a first example, along a scale 661, a minimum qualification is shown. The minimum qualification can be a composite grade, made from the grades of both scale 662 and 663. For another example, a summary scale 664 may integrate different grades, such as those from scales 662 and 663.

Returning to FIG. 5, according to a next operation 540, if the test of operation 530 has failed, at least one control function of the tested circuit is disabled. Depending on the grading scheme, the control function can be disabled if the tested circuit failed one but not another test. Optionally and preferably, if all the operative functions pass their respective tests, the tested circuit is not disabled in any way, such as by disabling its control function.

Disabling the control function is intended to disable in part or in whole the circuit, and can be performed in a number of ways. Various such ways are described later in this document.

Referring now to FIG. 6C, wafer 600 of FIG. 6A is shown again. When operation 540 is performed, the circuits have been divided into two subgroups, namely first subgroup 631 and second subgroup 632. Subgroup 632 is those of the integrated circuits that have had their control function disabled, as a result of operation 540. Subgroup 631 is those of the integrated circuits on wafer 600 that have not had their control function disabled, whether they passed the test of operation 530 or not. Preferably all circuits are tested, and treated uniformly. In FIG. 6C, the wafer has not been cut, and is still a single piece.

Returning to FIG. 5, according to a next operation 550, one or more chips are separated from a remainder of the wafer. Operation 550 is performed preferably after operation 530 has been performed for all the circuits on the wafer, and operation 540 for those that fail one or more of the tests of operation 530. Separating is preferably performed for all the circuits of the wafer, such as by dicing, etc., as is known in the art.

Referring now to FIG. 6D, a wafer 600 of FIG. 6C is shown, as it is being separated into integrated circuit (IC) chips 624. After cutting, all chips 624 can be presented together, in which case their aggregate is still called a wafer. Such presenting is preferably by holding them together in their places relative to each other, although that is not necessary for practicing the present invention.

In FIG. 6D, Each chip 624 may include one or more integrated circuits 630. In many embodiments, each chip 624 includes just one of integrated circuits 630. This one integrated circuit can be either from first subgroup 631 or from second subgroup 632, as will be seen in the two examples below.

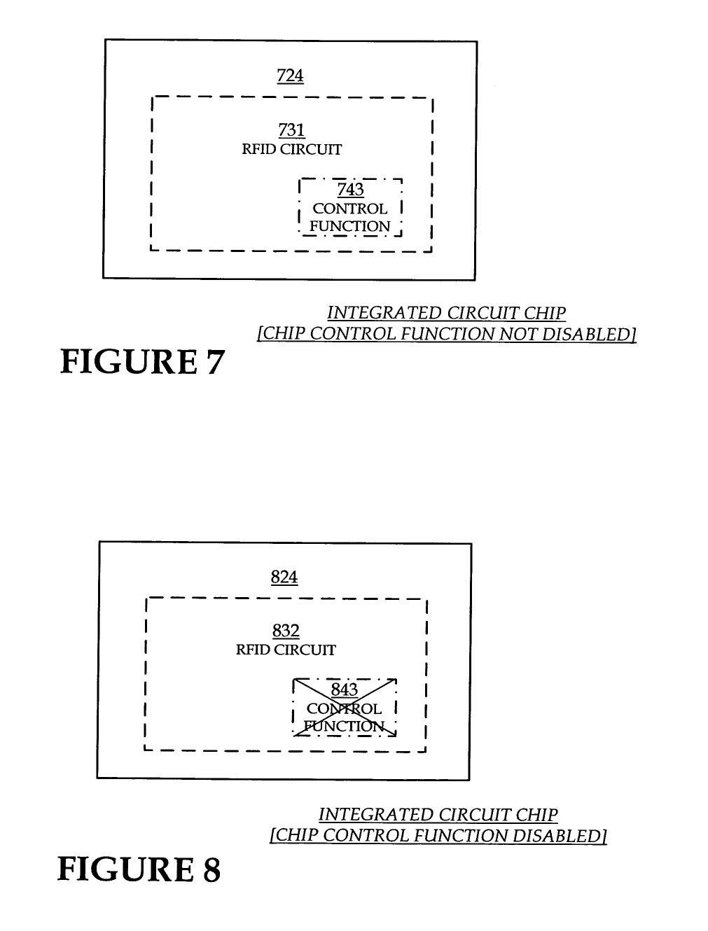

FIG. 7 is a block diagram of a chip whose IC has not been disabled. More particularly, IC 724 can arise as described above for IC 624, and where it further includes an RFID IC 731 that is similar to one of ICs 631 of the first subgroup in FIG. 6D. So, a control function 743 of it has not been disabled, and therefore it is expected that IC 724 will probably work fine, and can be assembled into the tag of FIG. 2.

FIG. 8 is a block diagram of a chip whose IC has been disabled in some way. More particularly, IC 824 can arise as described above for IC 624, and where it further includes an RFID IC 832 that is similar to one of ICs 632 of the second subgroup in FIG. 6D. IC 824 has failed some tests. Therefore, because of operation 540 of the invention, a control function 843 of it has been disabled.

As mentioned above, disabling can be performed in any number of ways. Some such ways are now described. In most of these ways, disabling can be performed by first probing the wafer. Or the IC can include an on-chip antenna, and RF energy can be directed to the antenna to disable the control function.

In a number of embodiments, the tested circuit includes a component, and disabling includes changing the component. This way the function of the component, also known as the control function is disabled or changed. The component can be changed in a way that it becomes destroyed, or disconnected, and so on, as will be evident for a person skilled in the art in view of the present description. Various examples are now described, of circuits that were first described with reference to FIG. 4, and were further disabled in some way, as was done for the circuits 632 of the second subgroup.

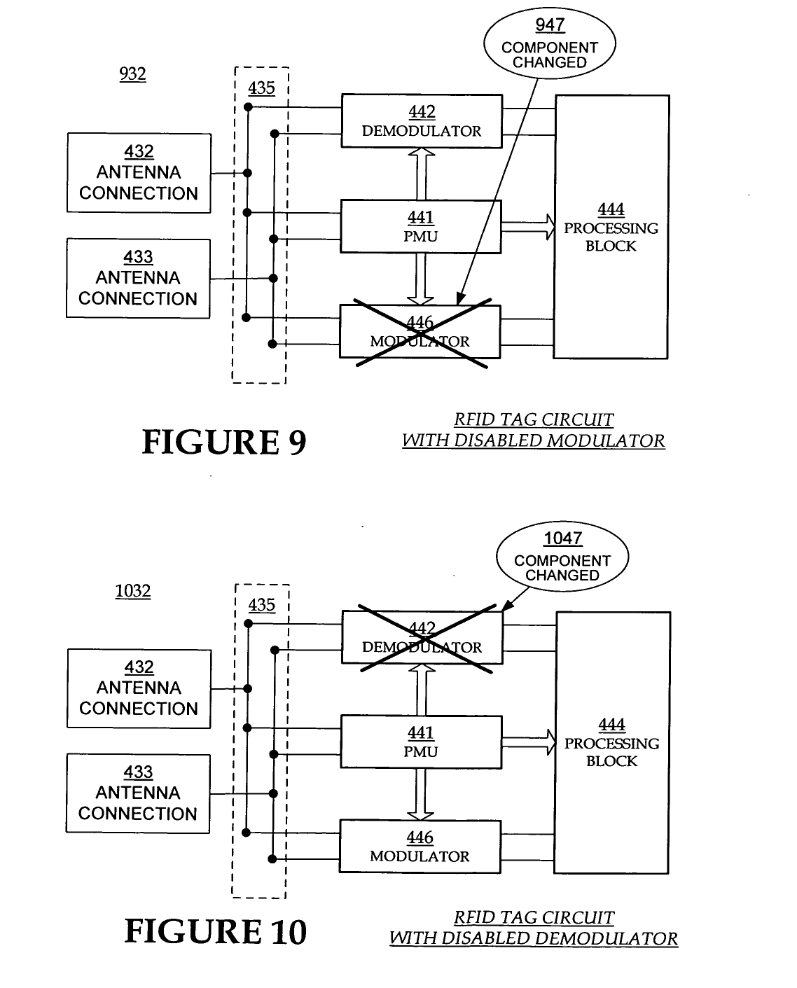

FIG. 9 is a block diagram of RFID circuit 932, having the components already described with reference to FIG. 4. In addition, according to a comment 947, its modulator 446 is a component that has been changed. Accordingly, the control function of modulation has been disabled.

FIG. 10 is a block diagram of another RFID circuit 1032, having the components already described with reference to FIG. 4. In addition, according to a comment 1047, its demodulator 442 is a component that has been changed. Accordingly, the control function of demodulation has been disabled.

Other examples are also possible. Fore example, the component can include a fuse that is normally closed, and changing the component can include cutting the fuse. Or the component can include an anti-fuse that is normally open, and changing the component can include shorting the anti-fuse. Or the component can include a power bus, and changing the component can includes opening the power bus, thus preventing its control function of delivering power to all components.

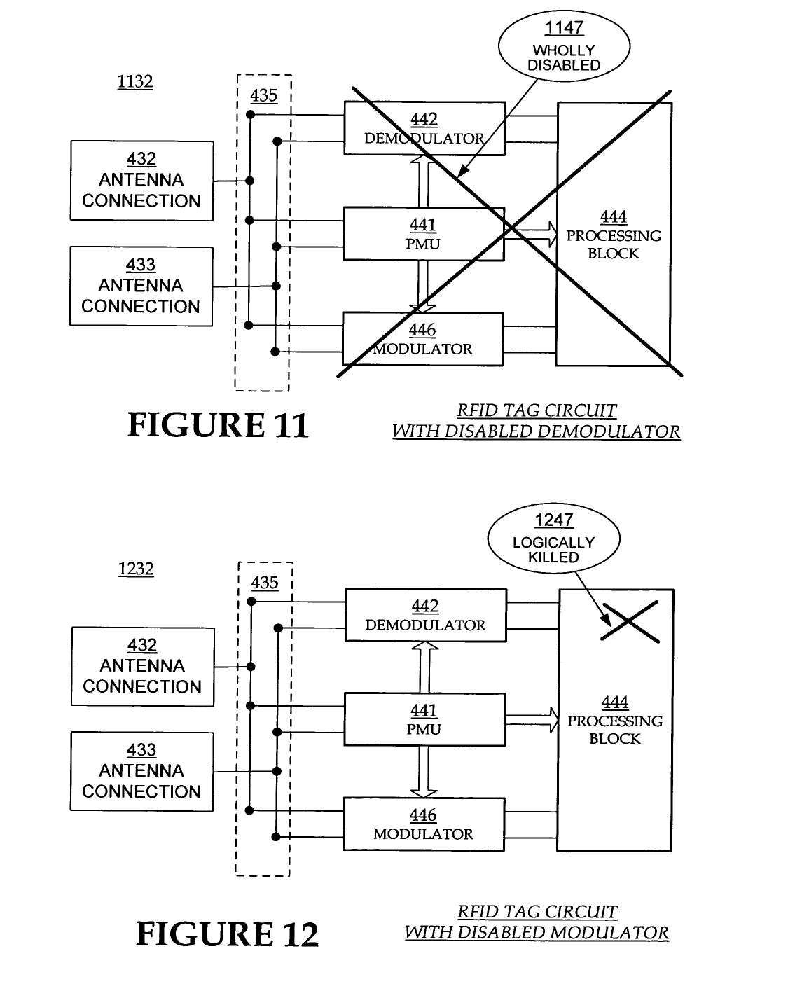

FIG. 11 is a block diagram of yet another RFID circuit 1132, having the components already described with reference to FIG. 4. In addition, according to a comment 1147, circuit 1132 has been wholly disabled, losing all its function.

FIG. 12 is a block diagram of one more RFID circuit 1232, having the components already described with reference to FIG. 4. In addition, according to a comment 1247, its processing block 444 is a component that has been changed, in this case logically killed. Accordingly, the control function of processing has been disabled. This can be performed in a number of ways.

In some embodiments, circuit 1232 includes a mechanism for becoming logically killed, and disabling is performed by actuating that mechanism. Actuating can be performed by probing the wafer, or directing RF energy at an on-chip antenna of circuit 1232. For example, the mechanism can include a password that can be implemented by non volatile memory, and so on.

In all of these embodiments, the initial desire was to produce an IC 624 that can be used as IC 224 for forming a tag 220. In circuit 1232, however, manufacture has been performed with one or more defects, and therefore circuit 1232 may not be used for forming tag 220. All those of the similar circuits on the wafer, however, which were not manufactured defectively, could be eventually completed as RFID tags. In that case, the mechanism for logically killing circuit 1232 would be the same mechanism that would be responsive to a wirelessly received KILL command, for logically killing the eventually completed tag. Such a KILL command is described, for example, in the above mentioned Gen2 Spec.

The above mentioned processes, ending with operation 550 of FIG. 5, can result in a group of chips 624, some of which are desirable (e.g. chips like chip 724), and some of which are undesirable (e.g. chips like chip 824). It is preferable to then separate the desirable ones from the undesirable ones.

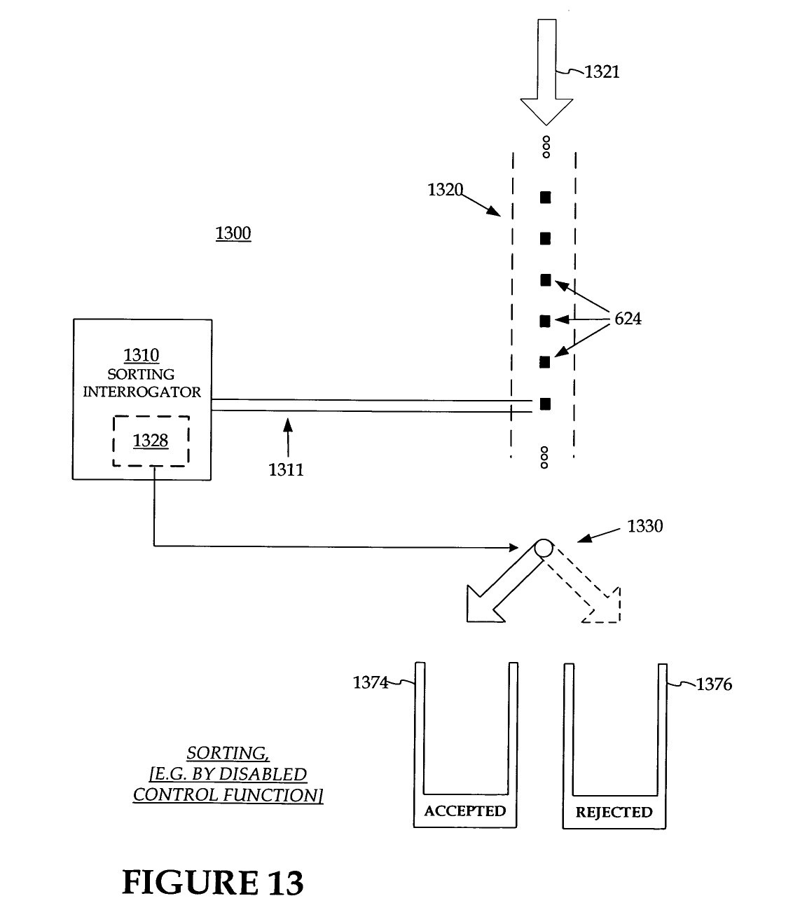

FIG. 13 describes a system 1300 for separating chips 624 into desirable and undesirable ones. The chips 624 are carried on a conveyor belt 1320, which is moving in a direction 1321. A sorting interrogator 1310 interrogateschips 624. It can do this by probes 1311, or by RF energy, and so on.

Interrogation reveals whether each of chips 624 is desirable or not. In some instances, the control function is tested, instead of the operative function.

Software 1328 associated with interrogator 1310 controls a switch 1330. Accordingly, chips 624 are routed to either an accepted bin 1374, or to a rejected bin 1376.

In this description, numerous details have been set forth in order to provide a thorough understanding. In other instances, well-known features have not been described in detail in order to not obscure unnecessarily the description.

A person skilled in the art will be able to practice the present invention in view of this description, which is to be taken as a whole. The specific embodiments as disclosed and illustrated herein are not to be considered in a limiting sense. Indeed, it should be readily apparent to those skilled in the art that what is described herein may be modified in numerous ways. Such ways can include equivalents to what is described herein.

The following claims define certain combinations and subcombinations of elements, features, steps, and/or functions, which are regarded as novel and non-obvious. Additional claims for other combinations and subcombinations may be presented in this or a related document.

What is claimed is:

1. A method comprising:
forming a plurality of RFID integrated circuits on a wafer;
performing a first test on a first operative function of one of the RFID circuits; and
if the first operative function fails the first test, disabling at least a control function of the tested circuit; and
then separating from a remainder of the wafer a chip that includes the tested circuit.

2. The method of claim 1, further comprising:
if the first operative function passes the first test, not disabling the tested circuit.

3. The method of claim 1, in which
the wafer is physically probed to test the first operative function.

4. The method of claim 1, in which
the tested circuit includes an on-chip antenna, and
RF energy is directed at the antenna to test the first operative function.

5. The method of claim 1, in which
the first test results in a grade, and
the first operative function fails the first test if the grade is less than a threshold.

6. The method of claim 1, in which
the first test results in a grade, and
the first operative function fails the first test if the grade is more than a threshold.

7. The method of claim 1, further comprising:
performing a second test on a second operative function of the tested circuit; and
in which the control function is disabled if at least one of the first and the second operative functions fails its respective test.

8. The method of claim 1, in which
the wafer is physically probed to disable the control function.

9. The method of claim 1, in which
the tested circuit includes an on-chip antenna, and
RF energy is directed at the antenna to disable the control function.

10. The method of claim 1, in which
the tested circuit includes a component, and
disabling includes changing the component.

11. The method of claim 10, in which
the component is a modulator.

12. The method of claim 10, in which
the component is a demodulator.

13. The method of claim 10, in which
the component includes a fuse that is normally closed, and
changing the component includes cutting the fuse.

14. The method of claim 10, in which
the component includes an anti-fuse that is normally open, and
changing the component includes shorting the anti-fuse.

15. The method of claim 10, in which
the component includes a power bus, and
changing the component includes opening the power bus.

16. The method of claim 1, in which
if the first operative function fails the first test, the tested circuit is wholly disabled.

17. The method of claim 1, in which
the tested circuit includes a mechanism for becoming logically killed, and
disabling is performed by actuating the mechanism to logically kill the tested circuit.

18. The method of claim 17, in which
the wafer is physically probed to actuate the mechanism.

19. The method of claim 17, in which
the tested circuit includes an on-chip antenna, and
RF energy is directed at the antenna to actuate the mechanism.

20. The method of claim 17, in which
if the tested circuit were eventually completed as an RFID tag, the mechanism would be responsive to a wirelessly received KILL command for logically killing the tag.

21. A wafer comprising formed thereon a plurality of similar integrated RFID circuits, a first operative function of the RFID circuits having been tested by a first test, and in which
a first subgroup of the circuits, whose first operative function has passed the first test, have not had one of their control functions disabled, and
a second subgroup of the circuits, whose first operative function has failed the first test, have had one of their control functions disabled.

22. The wafer of claim 21, in which
the wafer is a single piece.

23. The wafer of claim 21, which
has been further separated into chips, some of which contain respective ones of the integrated RFID circuits.

24. The wafer of claim 21, in which
the RFID circuits include a component, and
the RFID circuits of the second subgroup have been disabled by the component having been changed.

25. The wafer of claim 24, in which
the component is a modulator.

26. The wafer of claim 24, in which
the component is a demodulator.

27. The wafer of claim 24, in which
the component includes a fuse that is normally closed, and
the fuse has been changed by being cut.

28. The wafer of claim 24, in which
the component includes an anti-fuse that is normally open, and
the anti-fuse has been changed by being shorted.

29. The wafer of claim 24, in which
the component includes a power bus.

30. The wafer of claim 21, in which
the circuits include respective on-chip antennas, and
the circuits of the second subgroup have had their control function disabled by directing RF energy at their antennas.

31. The wafer of claim 21, in which
the circuits of the second subgroup have been wholly disabled.

32. The wafer of claim 21, in which
the circuits include respective mechanisms for becoming logically killed, and
the circuits of the second subgroup have been disabled by actuating the mechanism to logically kill them.

33. The wafer of claim 32, in which
if the circuits of the first subgroup were eventually completed as respective RFID tags, their mechanism would be responsive to a wirelessly received KILL command for logically killing the respective RFID tags.
